(19) United States
(12) Patent Application Publication
(10) Pub. No.: US 2012/0069629 A1
(43) Pub. Date: Mar. 22, 2012

(54) SEMICONDUCTOR MEMORY DEVICE

(76) Inventors: Yoshihiro UEDA, Yokohama-shi (JP); Akira KATAYAMA, Yamato-shi (JP); Ryousuke TAKIZAWA, Naka-gun (JP)

(21) Appl. No.: 13/234,587

(22) Filed: Sep. 16, 2011

(30) Foreign Application Priority Data
Sep. 21, 2010 (JP) 2010-211378

(51) Int. Cl. G11C 11/00; G11C 7/06; G11C 17/16

(52) U.S. Cl. 365/148; 365/225.7; 365/210.1

(57) ABSTRACT

According to one embodiment, a semiconductor memory device includes a first reference cell being arranged in a first cell array, and a plurality of first fuse cells being arranged in the first cell array. The first reference cell and the plurality of first fuse cells are arranged on the same row or column.

### CROSS-REFERENCE TO RELATED APPLICATIONS

This application is based upon and claims the benefit of priority from prior Japanese Patent Application No. 2010-211378, filed Sep. 21, 2010, the entire contents of which are incorporated herein by reference.

### FIELD

Embodiments described herein relate generally to a semiconductor memory device having fuse cells.

### BACKGROUND

Nonvolatile memories include resistance change memories such as an MRAM (Magnetic Random Access Memory), ReRAM (Resistance Random Access Memory), and PRAM (Phase-change Random Access Memory).

There exists, for these memories, a technique of implementing a fuse for storing the operation condition of peripheral circuit control using a nonvolatile cell. This cell is called a fuse cell. More specifically, all cells of some rows or columns of a cell array are assigned as fuse cells.

However, when rows or columns to be exclusively used for fuse cells are added to the cell array, the chip area increases.

### BRIEF DESCRIPTION OF THE DRAWINGS

FIG. 1 is a block diagram showing the schematic circuit arrangement of a resistance change memory according to the first embodiment;

FIG. 2 is a schematic view concerning the read operation of fuse cells FC in the resistance change memory according to the first embodiment;

FIG. 3 is a block diagram concerning the read operation of the fuse cells FC in the resistance change memory according to the first embodiment;

FIG. 4 is a circuit diagram showing the arrangement of a memory cell MC according to the first embodiment;

FIG. 5 is a schematic view showing the arrangement of an MTJ element 21 according to the first embodiment;

FIGS. 6A and 6B are views showing the low resistance state and the high resistance state of the MTJ element 21 according to the first embodiment;

FIG. 7 is a circuit diagram showing the arrangement of a reference cell RC according to the first embodiment;

FIG. 8 is a block diagram showing the arrangement of a column decoder 13-1 according to the first embodiment;

FIG. 9 is a circuit diagram showing the arrangement of a multiplexer MUX included in the column decoder 13-1 according to the first embodiment;

FIG. 10 is a circuit diagram showing the arrangement of a fuse latch circuit 15-1 according to the first embodiment;

FIG. 11 is a timing chart showing the operation of the fuse latch circuit 15-1 according to the first embodiment;

FIG. 12 is a block diagram showing the schematic circuit arrangement of a resistance change memory according to the second embodiment;

FIG. 13 is a block diagram showing the arrangement of a row decoder 12-1 according to the second embodiment;

FIG. 14 is a schematic view showing the arrangement of a resistance change element 21 used in an ReRAM according to the third embodiment; and

FIG. 15 is a schematic view showing the arrangement of the resistance change element 21 used in a RRAM according to the third embodiment.

### DETAILED DESCRIPTION

In general, according to one embodiment, a semiconductor memory device comprises a first reference cell being arranged in a first cell array, and a plurality of first fuse cells being arranged in the first cell array. The first reference cell and the plurality of first fuse cells are arranged on the same row or column.

The embodiment will now be described with reference to the accompanying drawings. In the following description, the same reference numerals denote the same parts throughout the drawings.

### [1] First Embodiment

### [1-1] Circuit Arrangement of Resistance Change Memory

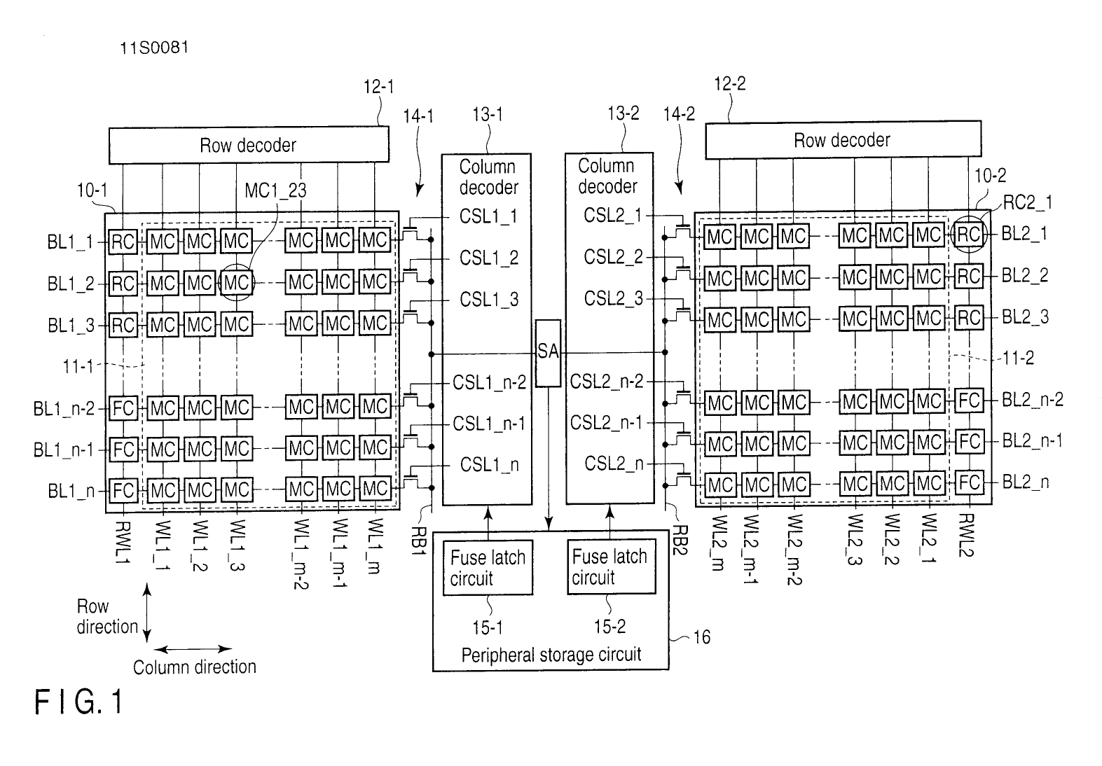

The schematic circuit arrangement of a resistance change memory according to the first embodiment will be described with reference to FIG. 1. FIG. 1 mainly illustrates a read system circuit. The resistance change memory of this embodiment includes a plurality of cell arrays. A simply diagram showing two cell arrays will be used here.

The resistance change memory comprises cell arrays 10-1 and 10-2, row decoders 12-1 and 12-2, column decoders 13-1 and 13-2, a sense amplifier SA, and a peripheral storage circuit 16.

The cell arrays 10-1 and 10-2 include memory cell arrays 11-1 and 11-2, respectively. Each of the memory cell arrays 11-1 and 11-2 includes (m×n) memory cells MC arranged in a matrix.

Each of the cell arrays 10-1 and 10-2 includes reference cells RC and fuse cells FC. The reference cells RC and the fuse cells FC are arranged adjacent to the memory cell arrays 11-1 and 11-2 in the column direction. Instead of providing the fuse cells FC on a row different from that of the reference cells RC, the reference cells RC and the fuse cells FC are provided on the same row. In this example, the total number of reference cells RC and fuse cells FC in each of the cell arrays 10-1 and 10-2 is n, which is the same as the number of memory cells MC in the row direction.

In the memory cell array 11-1, n bit lines BL1_1 to BL1_n (BL1) are disposed so as to run in the column direction. In the memory cell array 11-1, m word lines WL1_1 to WL1_m (WL1) are disposed so as to run in the row direction. The memory cells MC are arranged at the intersections between the bit lines BL1 and the word lines WL1. Each memory cell MC is connected to the corresponding bit line BL1 and word line WL1.

The reference cells RC and the fuse cells FC in the cell array 10-1 are connected to one reference word line RWL1 running in the row direction, and line up in the row direction. The reference cells RC and the fuse cells FC are connected to the bit lines BL1_1 to BL1_n.

Similarly, in the memory cell array 11-2, n bit lines BL2_1 to BL2_n (BL2) are disposed so as to run in the column direction. In the memory cell array 11-2, m word lines WL2_1 to WL2_m (WL2) are disposed so as to run in the row direction. The memory cells MC are arranged at the intersections between the bit lines BL2 and the word lines WL2. Each memory cell MC is connected to the corresponding bit line BL2 and word line WL2.

The reference cells RC and the fuse cells FC in the cell array 10-2 are connected to one reference word line RWL2 running in the row direction, and line up in the row direction. The reference cells RC and the fuse cells FC are connected to the bit lines BL2_1 to BL2_n.

Note that the reference cells RC and the fuse cells FC are separately arranged on the upper and lower sides in FIG. 1. However, the present embodiment is not limited to this. For example, the reference cells RC and the fuse cells FC may be arranged alternately. In addition, the total number of reference cells RC and fuse cells FC need not always be the same as the number n of columns, and may be smaller than the number n of columns. In the cell arrays 10-1 and 10-2, the number of reference cells RC and the number of fuse cells FC may be equal or different. For example, at least one reference cell RC may be set, and all the remaining cells may be set as the fuse cells FC. As for setting the reference cells RC, specific cells in the cell arrays 10-1 and 10-2 may be preset as the reference cells at the time of manufacture of the resistance change memory. Alternatively, the reference cells may be set in the test process after the manufacture.

The row decoder 12-1 is connected to the word lines WL1 and the reference word line RWL1. The row decoder 12-2 is connected to the word lines WL2 and the reference word line RWL2. The row decoder 12-1 selects one of the word lines WL1 and the reference word line RWL1 based on an address. The row decoder 12-2 selects one of the word lines WL2 and the reference word line RWL2 based on an address.

More specifically, when the memory cell MC to be accessed is included in the memory cell array 11-1 connected to the row decoder 12-1, the row decoder 12-1 selects one of the word lines WL1_1 to WL1_m. If the memory cell MC to be accessed is not included in the memory cell array 11-1 connected to the row decoder 12-1, the row decoder 12-1 selects the reference word line RWL1. Similarly, when the memory cell MC to be accessed is included in the memory cell array 11-2 connected to the row decoder 12-2, the row decoder 12-2 selects one of the word lines WL2_1 to WL2_m. If the memory cell MC to be accessed is not included in the memory cell array 11-2 connected to the row decoder 12-2, the row decoder 12-2 selects the reference word line RWL2.

The n bit lines BL1 are connected to a read data line RB1 via a column selection circuit 14-1. The column selection circuit 14-1 includes column selection transistors in number corresponding to the n bit lines BL1. Each column selection transistor is formed from, for example, an N-channel MOS transistor. The gates of the n column selection transistors included in the column selection circuit 14-1 are connected to the column decoder 13-1 via column selection lines CSL1_1 to CSL1_n.

Similarly, the n bit lines BL2 are connected to a read data line RB2 via a column selection circuit 14-2. The column selection circuit 14-2 includes column selection transistors in number corresponding to the n bit lines BL2. The gates of the n column selection transistors included in the column selection circuit 14-2 are connected to the column decoder 13-2 via column selection lines CSL2_1 to CSL2_n.

The sense amplifier SA shared by the memory cell arrays 11-1 and 11-2 is connected to the read data lines RB1 and RB2. The sense amplifier SA detects and amplifies data of the accessed memory cell MC using a voltage or a current read out from the accessed memory cell MC to one of the read data lines RB1 and RB2 and a voltage or a current read out from the reference cell RC to the other of the read data lines RB1 and RB2.

The column decoder 13-1 selects one of the bit lines BL1 based on an address. The selection control of the bit line BL1 is done by selecting (activating) one of the column selection lines CSL1. Similarly, the column decoder 13-2 selects one of the bit lines BL2 based on an address. The selection control of the bit line BL2 is done by selecting (activating) one of the column selection lines CSL2. The detailed operation of the column decoder 13 will be described later.

The peripheral storage circuit 16 includes fuse latch circuits 15-1 and 15-2. The fuse latch circuits 15-1 and 15-2 hold information associated with optimum reference cell selection so as to select the reference cell RC that allows most accurate read. The optimum reference cell RC is selected using the information held in the fuse latch circuits 15-1 and 15-2.

The peripheral storage circuit 16 stores data of the fuse cells FC. Immediately after the chip with the resistance change memory is powered on, the data of the fuse cells FC are read out via the sense amplifier SA and stored in the peripheral storage circuit 16. In addition, the optimum reference cell RC is selected using the information in the peripheral storage circuit 16 including the fuse latch circuits 15-1 and 15-2. The operation condition of the peripheral control circuit may be set using information in a region of the peripheral storage circuit 16 excluding the fuse latch circuits 15-1 and 15-2.

In this embodiment, there is a degree of freedom in selecting the reference cell RC independently of the address of the memory cell MC. It is therefore possible to select the reference cell RC that allows the most accurate read (optimum reference cell selection method). In this method, the reference cells RC not in use exist. In this embodiment, the region of the reference cells RC not in use is assigned to the fuse cells FC. Hence, in this embodiment, the reference cells RC and the fuse cells FC line up on the same row.

### [1-2] Read Operation of Memory Cell MC

The read operation of the memory cell MC in the resistance change memory having the above-described arrangement will be explained with reference to FIG. 1. Assume that, for example, a memory cell MC1_23 arranged at the intersection between the word line WL1_3 and the bit line BL1_2 and indicated by a circle in the memory cell array 11-1 on the left side of FIG. 1 is selected.

In this case, the row decoder 12-1 selects (activates) the word line WL1_3 to connect the memory cell MC1_23 and the bit line BL1_2. In addition, the column decoder 13-1 activates the column selection line CSL1_2 to connect the memory cell MC1_23 to the sense amplifier SA via the read data line RB1.

On the other hand, the reference cell RC is selected from the right block. That is, the row decoder 12-2 activates the reference word line RWL2 in accordance with the activation of the word line WL1_3.

The column decoder 13-2 controls to always activate the column selection line CSL2_1 independently of the address of the memory cell MC1_23 to be accessed. A reference cell RC2_1 is connected to the sense amplifier SA via the read data line RB2. The sense amplifier SA detects and amplifies data of the memory cell MC1_23 using a voltage or a current read out from the memory cell MC1_23 to the read data line RB2 and a voltage or a current read out from the reference cell RC2_1 to the read data line RB2.

All the memory cells MC arranged in the left block are thus set to be read-accessed using the reference cell RC2_1. Since the reference cell RC is not selected depending on the address of the memory cell MC to be accessed, not all the cells connected to the reference word line RWL2 need be used as the reference cells RC. This enables to decrease the number of reference cells RC and use, as the fuse cells FC, the cells connected to the reference word line RWL2 but not in use as the reference cells RC.

Similarly, when the memory cell MC in the right block is selected, the column decoder 13-1 controls to always activate, for example, the column selection line CSL1_1 independently of the address of the memory cell MC to be accessed. All the memory cells MC arranged in the right block are thus read-accessed using a reference cell RC1_1. This enables to decrease the number of reference cells RC and use, as the fuse cells FC, the cells connected to the reference word line RWL1 but not in use as the reference cells RC.

This control makes it possible to consistently perform the read operation of the memory cell MC independently of whichever memory cell array is selected, the left memory cell array 11-1 or the right memory cell array 11-2. In this case, the total number of reference cells RC necessary for the read is two.

That is, the number of reference cells RC can be much smaller than in the prior art. Since the margin of the resistance variation of the reference cells RC can be made smaller, the read margin can easily be ensured.

Note that in this embodiment, a control operation that allows to select the reference cell RC may be performed. That is, it is possible to change the reference cell RC to be always selected independently of the address of the bit to be accessed. When, for example, the reference cell RC2_1 malfunctions, not the column selection line CSL2_1 but the column selection line CSL2_2 is always activated to make a reference cell RC2_2 connected to the bit line BL2_2 selectable. If the reference cell RC2_2 is a normal cell, any failure can be avoided. Note that even when the so-called reserve reference cell RC is selectable, as in this method, the total number of reference cells RC mounted on the chip can be set smaller than in the prior art. Hence, practicing the embodiment does not cause any increase in the chip size. In addition, the fuse cells FC can be set on the same row as that of the reference cells RC.

### [1-3] Read Operation of Fuse Cell FC

In the read operation of the fuse cell FC of this embodiment, the fuse cells FC in the two cell arrays 10-1 and 10-2 store complementary data. When read-accessing the fuse cell FC in one of the cell arrays 10-1 and 10-2, the fuse cell FC in one of the cell arrays 10-1 and 10-2 and the fuse cell FC in the other of the cell arrays 10-1 and 10-2 are connected to the inputs of the sense amplifier SA. The data of the fuse cell FC is determined by the difference in the resistance value.

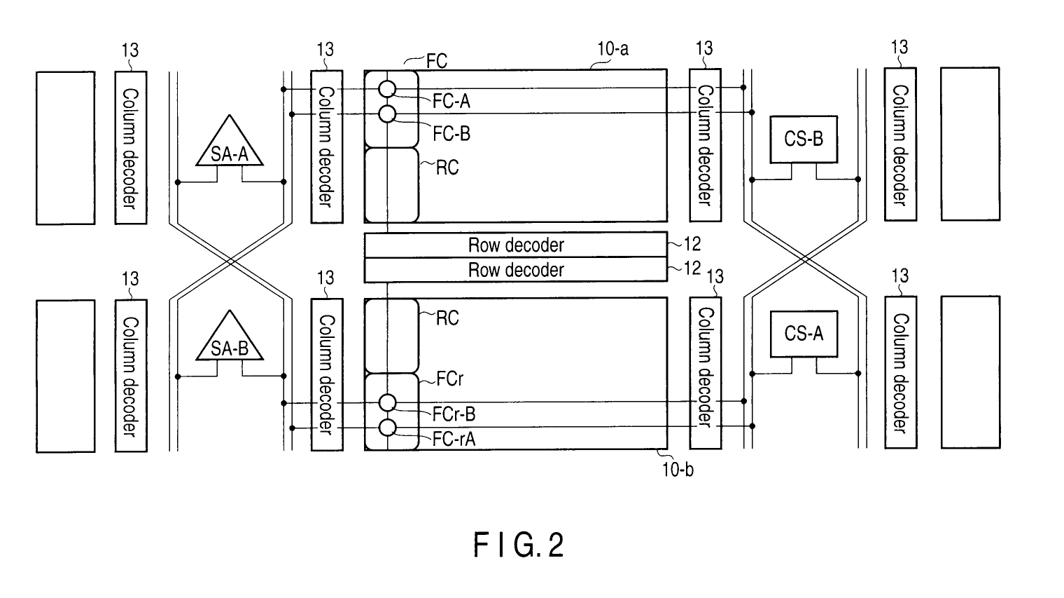

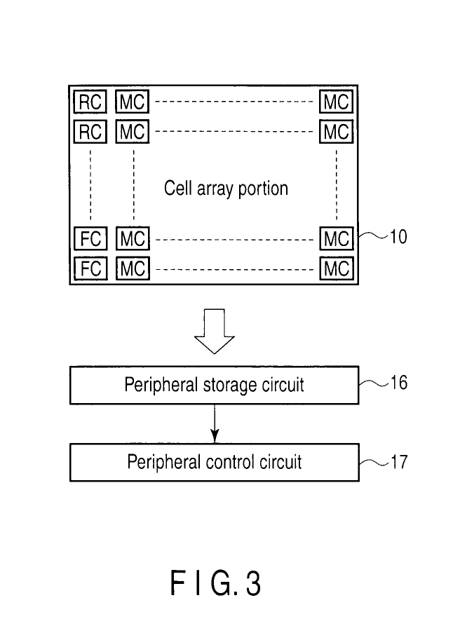

The read operation of the fuse cell FC in the resistance change memory according to the first embodiment will be described in detail with reference to FIGS. 2 and 3.

As shown in FIG. 2, when reading out data of a fuse cell FC-A in a cell array 10-a, a fuse cell FCr-A in an adjacent cell array 10-b is used as a reference cell. Hence, the fuse cells FC-A and FCr-A of the adjacent cell arrays 10-a and 10-b are connected to the complementary inputs of a sense amplifier SA-A. A read current and a reference current are supplied to the fuse cells FC-A and FCr-A, respectively, using a current sink CS-A. The sense amplifier SA-A compares the magnitudes of the read current and the reference current and thus determines the data of the fuse cell FC-A.

Similarly, when reading out data of a fuse cell FC-B in the cell array 10-a, a fuse cell FCr-B in the adjacent cell array 10-b is used as a reference cell. Hence, the fuse cells FC-B and FCr-B of the adjacent cell arrays 10-a and 10-b are connected to the complementary inputs of a sense amplifier SA-B. A read current and a reference current are supplied to the fuse cells FC-B and FCr-B, respectively, using a current sink CS-B. The sense amplifier SA-B compares the magnitudes of the read current and the reference current and thus determines the data of the fuse cell FC-B.

Note that when read-accessing a fuse cell, the fuse cell to be used as the reference cell is not limited to the fuse cell present in the adjacent cell array. A fuse cell at any position is usable as far as it exists in a different cell array.

Such a read operation of the fuse cell FC is performed when the chip with the resistance change memory is powered on.

As shown in FIG. 3, upon powering on the chip with the resistance change memory, the data of the fuse cells FC are transferred from the cell arrays 10 to, for example, the SRAM fuse of the peripheral storage circuit 16. The operation of a peripheral control circuit 17 is adjusted based on the data in the peripheral storage circuit 16. In addition, the optimum reference cell RC is selected based on the data in the peripheral storage circuit 16.

According to the above-described read operation of the fuse cell FC, no reference cell to be exclusively used as the fuse cell FC need be provided by the 2-cell/bit method. Hence, according to this embodiment, the fuse cells FC can ensure a capacity of about 128 kB on a 1-GB chip.

### [1-4] Memory Cell

In this embodiment, an MRAM (Magnetic Random Access Memory) will be exemplified as the resistance change memory (semiconductor memory device).

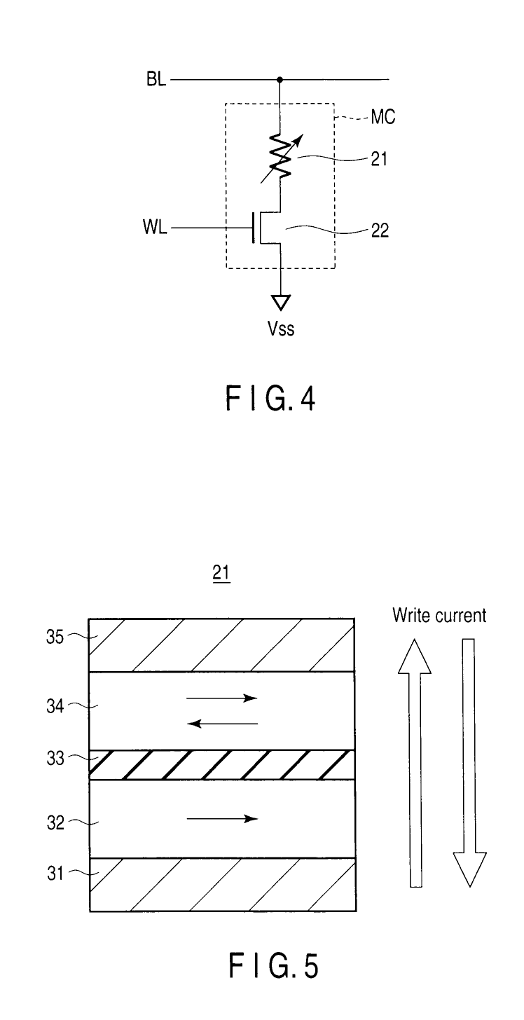

FIG. 4 is a circuit diagram showing the arrangement of the memory cell MC. The memory cell MC comprises a resistance change element (MTJ element) 21 and a selection transistor 22. The selection transistor 22 is formed from, for example, an N-channel MOS transistor. One terminal of the MTJ element 21 is connected to the bit line BL. The other terminal is connected to the drain of the selection transistor 22. The gate of the selection transistor 22 is connected to the word line WL. The source of the selection transistor 22 is grounded via, for example, a source line (a ground voltage Vss is applied).

FIG. 5 is a schematic view showing the arrangement of the MTJ element 21. The MTJ element 21 is formed by sequentially stacking a lower electrode 31, a fixed layer 32, an intermediate layer 33, a recording layer (free layer) 34, and an upper electrode 35. Note that the stacking order of the layers included in the MTJ element 21 may be reversed.

The fixed layer 32 is made of a ferromagnetic material and has a fixed magnetization direction. For example, providing an anti-ferromagnetic layer (not shown) adjacent to the fixed layer 32 allows to fix the magnetization direction of the fixed layer 32. The free layer 34 is made of a ferromagnetic material and has a variable magnetization direction. The intermediate layer 33 is made of a non-magnetic material. More specifically, a non-magnetic metal, a non-magnetic semiconductor, an insulator, or the like is usable.

The direction of easy magnetization of the fixed layer 32 and the free layer 34 can be either perpendicular to the film surface (perpendicular magnetization) or parallel to the film surface (in-plane magnetization). The perpendicular magnetization type is suitable for micropatterning because it is unnecessary to control the element shape to determine the magnetization direction, unlike the in-plane magnetization type.

Note that each of the fixed layer 32 and the free layer 34 is not limited to a single layer, as illustrated, and may have a layered structure including a plurality of ferromagnetic layers. In addition, each of the fixed layer 32 and the free layer 34 may have an anti-ferromagnetic coupling structure including a first ferromagnetic layer, a non-magnetic layer, and a second ferromagnetic layer in which the first and second ferromagnetic layers are magnetically coupled (interlayer exchange coupling) such that their magnetization directions are set in an anti-parallel state, or a ferromagnetic coupling structure in which the first and second ferromagnetic layers are magnetically coupled (interlayer exchange coupling) such that their magnetization directions are set in a parallel state.

The MTJ element 21 need not always have the illustrated single junction structure but may have a double junction structure. The MTJ element 21 with the double junction structure has a layered structure formed by sequentially stacking a first fixed layer, a first intermediate layer, a free layer, a second intermediate layer, and a second fixed layer. Such a double junction structure can easily control magnetization switching of the free layer 34 caused by spin transfer.

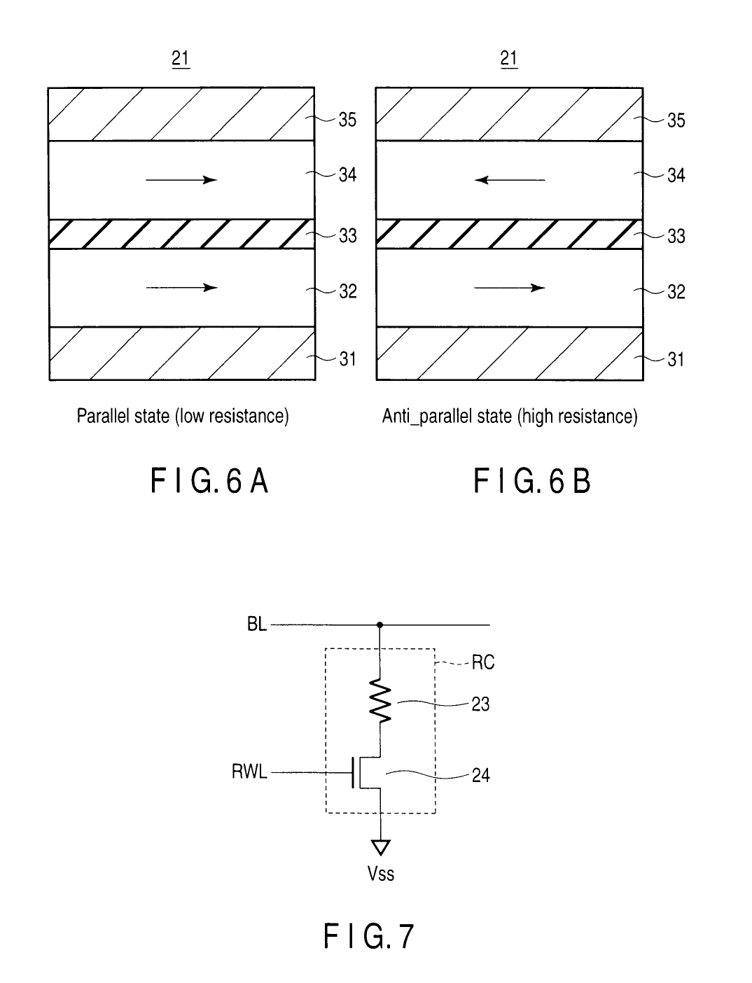

FIGS. 6A and 6B are views showing the low resistance state and the high resistance state of the MTJ element 21. The low resistance state and the high resistance state of the MTJ element 21 in the spin transfer torque writing method will be described below. Note that in this description, a current indicates an electron flow.

The parallel state (low resistance state) in which the magnetization directions of the fixed layer 32 and the free layer 34 are parallel will be described first. In this case, a current flowing from the fixed layer 32 to the free layer 34 is supplied. The majority of electrons out of the electrons that have passed through the fixed layer 32 has a spin parallel to the magnetization direction of the fixed layer 32. When the spin momentum of the majority of electrons is transferred to the free layer 34, the spin torque is applied to the free layer 34 so that the magnetization direction of the free layer 34 becomes parallel to that of the fixed layer 32. In this parallel arrangement, the resistance value of the MTJ element 21 is minimized. This state is defined as “0” data.

The anti-parallel state (high resistance state) in which the magnetization directions of the fixed layer 32 and the free layer 34 are anti-parallel will be described next. In this case, a current flowing from the free layer 34 to the fixed layer 32 is supplied. The majority of electrons out of the electrons that have been reflected by the fixed layer 32 has a spin anti-parallel to the magnetization direction of the fixed layer 32. When the spin momentum of the majority of electrons is transferred to the free layer 34, the spin torque is applied to the free layer 34 so that the magnetization direction of the free layer 34 becomes anti-parallel to that of the fixed layer 32. In this anti-parallel arrangement, the resistance value of the MTJ element 21 is maximized. This state is defined as “1” data.

### [1-5] Reference Cell RC

FIG. 7 is a circuit diagram showing the arrangement of the reference cell RC. The reference cell RC comprises a fixed resistance element 23 and a selection transistor 24. The selection transistor 24 is formed from, for example, an N-channel MOS transistor. One terminal of the fixed resistance element 23 is connected to the bit line BL. The other terminal is connected to the drain of the selection transistor 24. The gate of the selection transistor 24 is connected to the reference word line RWL. The source of the selection transistor 24 is grounded via, for example, a source line (the ground voltage Vss is applied).

The fixed resistance element 23 is fixed to an intermediate resistance value (reference value) between the low resistance state and the high resistance state of the memory cell MC. The fixed resistance element 23 is formed by the same process as that of the MTJ element 21, and has the same layered structure as that of the MTJ element 21 in general. The method of fixing the resistance of the fixed resistance element 23 to the predetermined reference value can be implemented by, for example, changing the areas of the two ferromagnetic layers while fixing their magnetization directions.

### [1-6] Fuse Cell FC

The fuse cell FC has the MTJ element 21 and the selection transistor 22, like the above-described memory cell MC. The fuse cell FC has the same arrangement as that of the memory cell MC, and a detailed description thereof will not be repeated.

### [1-7] Column Decoder

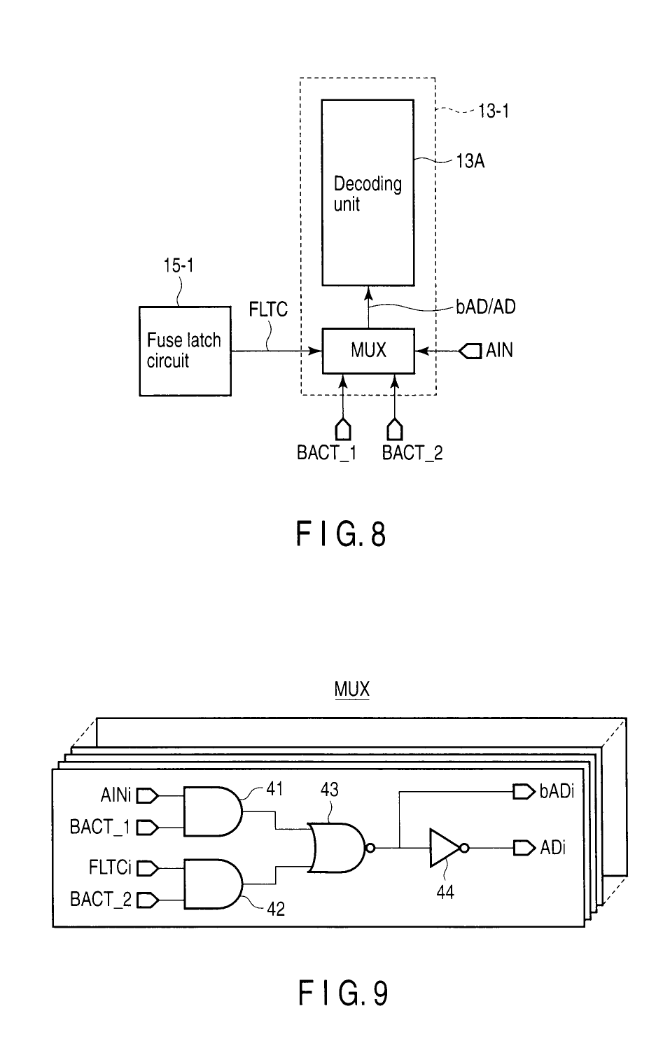

The arrangement of the column decoder 13 will be described with reference to FIGS. 8 and 9. FIG. 8 is a block diagram showing the arrangement of the column decoder 13-1. FIG. 9 is a circuit diagram showing the arrangement of an example of a multiplexer MUX included in the column decoder 13-1 shown in FIG. 8.

As shown in FIG. 8, the column decoder 13-1 comprises a decoding unit 13A and the multiplexer MUX.

Two addresses are supplied to the multiplexer MUX. The two addresses are an external input address AIN corresponding to an access bit address and an address FLTC from the fuse latch circuit 15-1. The address FLTC to select the specific reference cell RC is programmed in the fuse latch circuit 15-1.

Switching of the two addresses AIN and FLTC is controlled by block activation signals BACT_1 and BACT_2. To access the memory cell MC included in the memory cell array 11-1 in FIG. 1, the block activation signal BACT_1 is activated. To access the memory cell MC included in the memory cell array 11-2, the block activation signal BACT_2 is activated.

More specifically, when the block activation signal BACT_1 is activated, the multiplexer MUX included in the column decoder 13-1 selects the address AIN, and outputs the address AIN as an address AD and the inverted signal of the address AIN as an address bAD. The addresses bAD and AD are supplied to the decoding unit 13A. On the other hand, when the block activation signal BACT_2 is activated, the multiplexer MUX included in the column decoder 13-1 selects the address FLTC, and outputs the address FLTC as the address AD and the inverted signal of the address FLTC as the address bAD.

The decoding unit 13A activates one of the column selection signals CSL1_1 to CSL1_n based on the addresses bAD and AD.

Note that the column decoder 13-2 provided in correspondence with the memory cell array 11-2 has the same arrangement as that of the column decoder 13-1 described above.

With the operation of the column decoder 13, the specific reference cell RC is always selected in a block that does not include the memory cell MC to be accessed.

As shown in FIG. 9, the multiplexer MUX comprises AND gates 41 and 42, a NOR gate 43, and an inverter 44.

An address AINi and the block activation signal BACT_1 are input to the first and second input terminals of the AND gate 41, respectively, wherein “i” represents an arbitrary one of n bits corresponding to the number of column selection signals CSL1. The output of the AND gate 41 is input to the first input terminal of the NOR gate 43.

An address FLTCi and the block activation signal BACT_2 are input to the first and second input terminals of the AND gate 42, respectively. The output of the AND gate 42 is input to the second input terminal of the NOR gate 43.

The NOR gate 43 outputs an address bADi. The output of the NOR gate 43 is input to the input terminal of the inverter 44. The inverter 44 outputs an address ADi.

Note that the multiplexer MUX included in the column decoder 13-2 can be implemented by replacing the block activation signals BACT_1 and BACT_2 in FIG. 9 with each other.

### [1-8] Fuse Latch Circuit

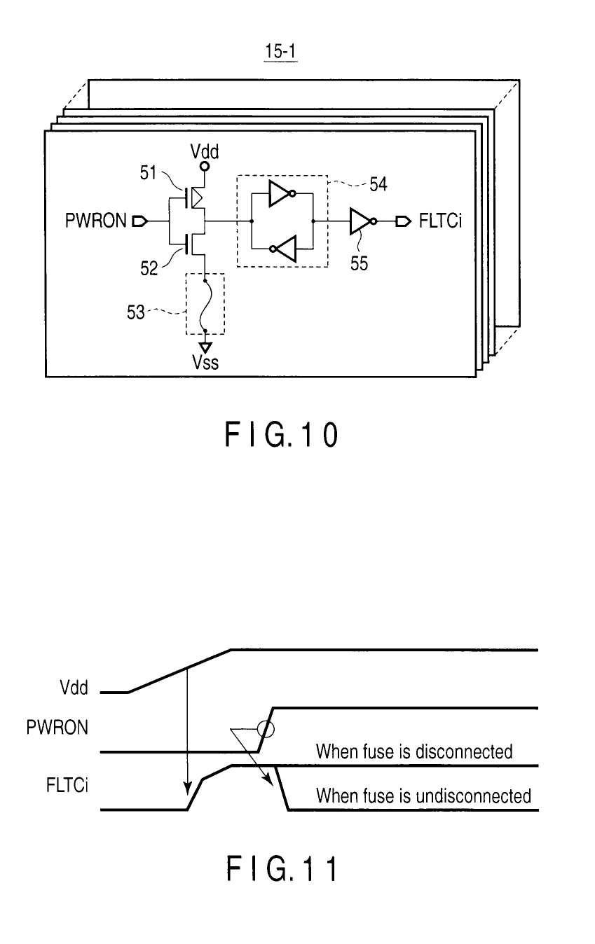

An example of the arrangement of the fuse latch circuit will be described with reference to FIG. 10. FIG. 10 is a circuit diagram showing the arrangement of the fuse latch circuit 15-1. The fuse latch circuit 15-2 has the same arrangement as that of the fuse latch circuit 15-1 in FIG. 10.

As shown in FIG. 10, the fuse latch circuit 15-1 comprises a P-channel MOS transistor 51, an N-channel MOS transistor 52, a fuse element 53, a latch circuit 54, and an inverter 55.

An external power on signal PWRON is supplied to the fuse latch circuit 15-1. The power on signal PWRON is set to high level upon power on and low level upon power off.

A power supply voltage Vdd is applied to the source of the P-channel MOS transistor 51. The power on signal PWRON is input to the gate of the P-channel MOS transistor 51. The drain of the P-channel MOS transistor 51 is connected to the drain of the N-channel MOS transistor 52.

The power on signal PWRON is input to the gate of the N-channel MOS transistor 52. The source of the N-channel MOS transistor 52 is connected to one terminal of the fuse element 53. The other terminal of the fuse element 53 is grounded. The fuse element 53 stores “0” or “1” data depending on whether or not it has been disconnected by a laser.

The drain of the P-channel MOS transistor 51 is connected to the input terminal of the latch circuit 54. The latch circuit 54 includes two inverters. The output of one inverter is connected to the input of the other inverter, and the output of the other is connected to the input of the one.

The output terminal of the latch circuit 54 is connected to the input terminal of the inverter 55. The inverter 55 outputs the address FLTCi.

### [1-9] Operation of Fuse Latch Circuit

The operation of the fuse latch circuit 15-1 will be described with reference to FIG. 11.

When the chip is powered on (Vdd), and the voltage in it rises to the voltage at which a logic circuit can operate, the address FLTC output from the fuse latch circuit 15-1 temporarily goes high. After power on, the address FLTC goes low for an address bit corresponding to the undisconnected fuse element 53 in synchronism with the rise of the power on signal PWRON that is an internal signal representing that initialization in the chip is completed. On the other hand, if the fuse element 53 has been disconnected, the address FLTC holds high level.

Only the fuse element corresponding to the least significant address is disconnected to program the address FLTC to (100 . . . 0). This address is assigned to the column selection line CSL1_1, thereby always selecting the column selection line CSL1_1. Only the fuse element corresponding to the address next to the least significant address is disconnected to program the address FLTC to (010 . . . 0). This address is assigned to the column selection line CSL1_2, thereby always selecting the column selection line CSL1_2. Introducing such a circuit and column selection line assignment makes it possible to select an arbitrary reference cell by programming the fuse element.

### [1-10] Effects

In the first embodiment, for example, when the memory cell MC arranged in the cell array 10-1 on the left side of the sense amplifier SA in FIG. 1 is selected, the specific reference cell RC arranged in the cell array 10-2 on the right side of the sense amplifier SA is always selected as the reference cell RC independently of the address of the selected memory cell MC. Cells that are arranged on the same row as that of the specific reference cell RC but not in use as the reference cells RC are set as the fuse cells FC.

Hence, in this embodiment, the fuse cells FC are arranged on the same row as that of the reference cells RC in one cell array 10-1 or 10-2. In this embodiment, it is therefore possible to implement the fuse cells FC without increasing the chip area, unlike a case in which a fuse cell region is newly provided on a row different from the row with the reference cells in one cell array cell array.

According to this embodiment, the memory cell MC arranged in one memory cell array 10-1 or 10-2 is read-accessed using the specific reference cell RC independently of the address of the memory cell MC to be accessed. For this reason, the total number of reference cells RC can be decreased. Since the margin of the resistance variation of the reference cells RC can be made smaller, the read margin can easily be ensured. As described above, in this embodiment, the specific reference cell RC of the plurality of reference cells RC is used, thereby implementing a highly accurate read operation.

Additionally, in this embodiment, it is possible to change the reference cell RC to be always selected independently of the address of the memory cell MC to be accessed. Control is thus changed to, when one reference cell RC malfunctions, always select another reference cell RC. This allows to avoid any chip failure. As a result, a large-capacity resistance change memory can be implemented at a low cost without lowering the yield.

### [2] Second Embodiment

In the first embodiment, the reference cells RC and the fuse cells FC are arranged adjacent to the memory cell arrays 11 in the column direction, and line up in the row direction. In the second embodiment, however, reference cells RC and fuse cells FC are arranged adjacent to memory cell arrays 11 in the row direction, and line up in the column direction.

Note that in the second embodiment, a description of the same points as in the first embodiment will be omitted or simplified, and points different from the first embodiment will be described.

### [2-1] Circuit Arrangement of Resistance Change Memory

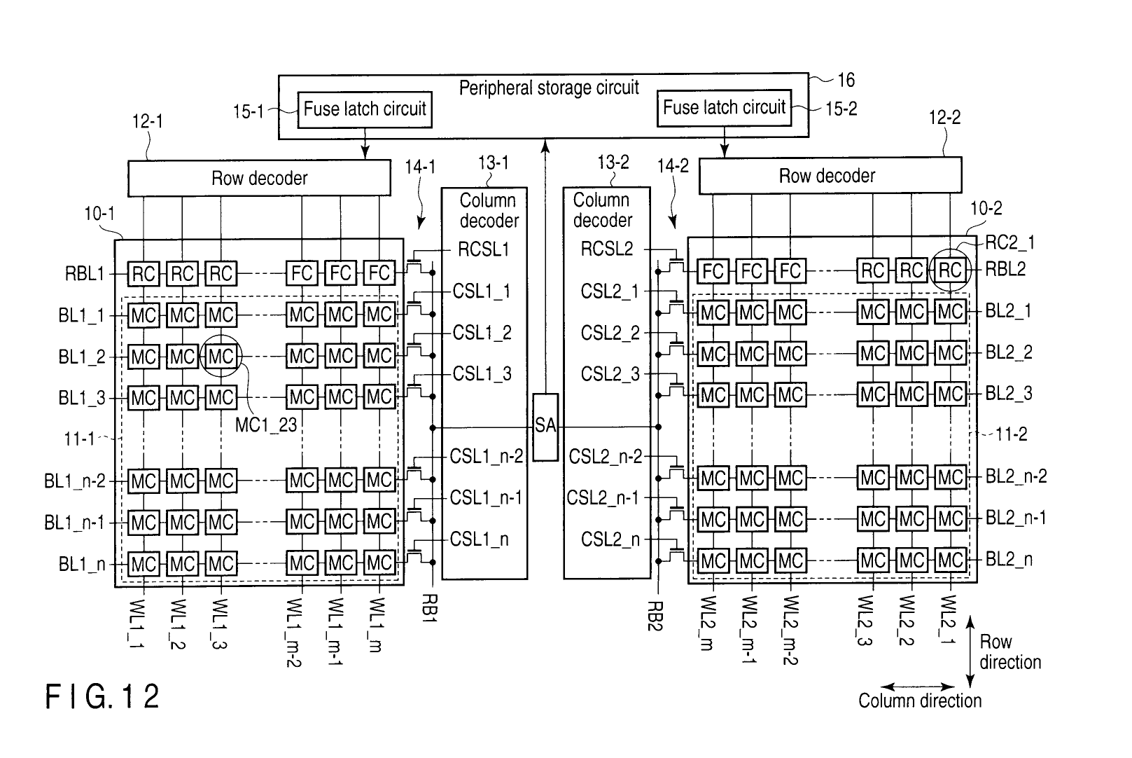

The schematic circuit arrangement of a resistance change memory according to the second embodiment will be described with reference to FIG. 12.

In a cell array 10-1, m reference cell RC and fuse cells FC in total are provided in correspondence with a memory cell array 11-1. The reference cells RC and the fuse cells FC are arranged adjacent to the memory cell array 11-1 in the row direction. The reference cells RC and the fuse cells FC are connected to one reference bit line RBL1 running in the column direction, and line up in the column direction. The m reference cells RC and fuse cells FC in total are connected to m word lines WL1_1 to WL1_m. The reference cells RC and the fuse cells FC in the cell array 10-1 are thus arranged on the same column.

Similarly, in a cell array 10-2, the m reference cell RC and fuse cells FC in total are provided in correspondence with a memory cell array 11-2. The reference cells RC and the fuse cells FC are arranged adjacent to the memory cell array 11-2 in the row direction. The reference cells RC and the fuse cells FC are connected to one reference bit line RBL2 running in the column direction, and line up in the column direction. The m reference cells RC and fuse cells FC in total are connected to m word lines WL2_1 to WL2_m. The reference cells RC and the fuse cells FC in the cell array 10-2 are thus arranged on the same column.

The reference bit line RBL1 is connected to a read data line RB1 via a column selection circuit 14-1. The gate of a column selection transistor included in the column selection circuit 14-1 and connected to the reference bit line RBL1 is connected to a column decoder 13-1 via a reference column selection line RCSL1. The reference bit line RBL2 is connected to a read data line RB2 via a column selection circuit 14-2. The gate of a column selection transistor included in the column selection circuit 14-2 and connected to the reference bit line RBL2 is connected to a column decoder 13-2 via a reference column selection line RCSL2.

The column decoder 13-1 selects one of column selection lines CSL1 and the reference column selection line RCSL1 based on an address. The column decoder 13-2 selects one of column selection lines CSL2 and the reference column selection line RCSL2 based on an address.

More specifically, when a memory cell MC to be accessed is included in the memory cell array 11-1 connected to the column decoder 13-1, the column decoder 13-1 selects one of the column selection lines CSL1. If the memory cell MC to be accessed is not included in the memory cell array 11-1 connected to the column decoder 13-1, the column decoder 13-1 selects the reference column selection line RCSL1. Similarly, when the memory cell MC to be accessed is included in the memory cell array 11-2 connected to the column decoder 13-2, the column decoder 13-2 selects one of the column selection lines CSL2. If the memory cell MC to be accessed is not included in the memory cell array 11-2 connected to the column decoder 13-2, the column decoder 13-1 selects the reference column selection line RCSL2.

The m word lines WL1 are connected to a row decoder 12-1. The row decoder 12-1 selects one of the word lines WL1 based on an address. The m word lines WL2 are connected to a row decoder 12-2. The row decoder 12-2 selects one of the word lines WL2 based on an address. The detailed operation of the row decoder 12 will be described later.

### [2-2] Read Operation of Memory Cell MC

The read operation of the memory cell MC in the resistance change memory having the above-described arrangement will be explained with reference to FIG. 12. Assume that, for example, a memory cell MC1_23 arranged at the intersection between the word line WL1_3 and the bit line BL1_2 and indicated by a circle in the memory cell array 11-1 on the left side of FIG. 12 is selected.

In this case, the row decoder 12-1 selects (activates) the word line WL1_3 to connect the memory cell MC1_23 and the bit line BL1_2. In addition, the column decoder 13-1 activates the column selection line CSL1_2 to connect the memory cell MC1_23 to a sense amplifier SA via the read data line RB1.

On the other hand, the reference cell RC is selected from the right block. That is, the column decoder 13-2 activates the reference column selection line RCSL2 in accordance with the activation of the column selection line CSL1_2 so that the reference bit line RBL2 is connected to the read data line RB2.

The row decoder 12-2 controls to always activate the word line WL2_1 independently of the address of the memory cell MC1_23 to be accessed. A reference cell RC2_1 is connected to the sense amplifier SA via the read data line RB2. The sense amplifier SA detects and amplifies data of the memory cell MC1_23 using a voltage or a current read out from the memory cell MC1_23 to the read data line RB2 and a voltage or a current read out from the reference cell RC2_1 to the read data line RB2.

All the memory cells MC arranged in the left block are thus set to be read-accessed using the reference cell RC2_1. Since the reference cell RC is not selected depending on the address of the memory cell MC to be accessed, not all the cells connected to the reference bit line RBL2 need be used as the reference cells RC. This enables to decrease the number of reference cells RC and use, as the fuse cells FC, the cells connected to the reference bit line RBL2 but not in use as the reference cells RC.

Similarly, when the memory cell MC in the right block is selected, the row decoder 12-1 controls to always activate, for example, the word line WL1_1 independently of the address of the memory cell MC to be accessed. All the memory cells MC arranged in the right block are thus read-accessed using a reference cell RC1_1. This enables to decrease the number of reference cells RC and use, as the fuse cells FC, the cells connected to the reference bit line RBL1 but not in use as the reference cells RC.

This control makes it possible to consistently perform the read operation of the memory cell MC independently of whichever memory cell array is selected, the left memory cell array 11-1 or the right memory cell array 11-2. In this case, the total number of reference cells RC necessary for the read is two. That is, the number of reference cells RC can be much smaller than in the prior art. Since the margin of the resistance variation of the reference cells RC can be made smaller, the read margin can easily be ensured.

Note that in this embodiment, a control operation that allows to select the reference cell RC may be performed. That is, it is possible to change the reference cell RC to be always selected independently of the address of the bit to be accessed. When, for example, the reference cell RC2_1 malfunctions, not the word line WL2_1 but the word line WL2_2 is always activated to make a reference cell RC2_2 connected to the word line WL2_2 and the reference bit line RBL2 selectable. If the reference cell RC2_2 is a normal cell, any failure can be avoided.

### [2-3] Row Decoder

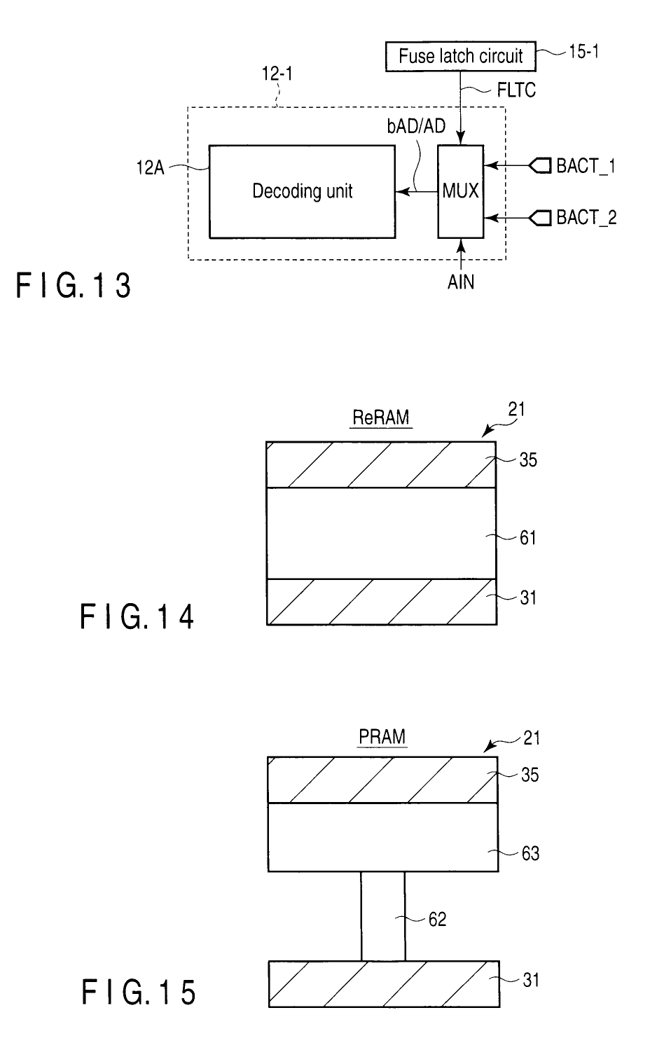

The arrangement of the row decoder 12-1 will be described with reference to FIG. 13.

As shown in FIG. 13, the row decoder 12-1 comprises a decoding unit 12A and a multiplexer MUX.

Two addresses are supplied to the multiplexer MUX. The two addresses are an external input address AIN corresponding to an access bit address and an address FLTC from a fuse latch circuit 15-1. The address FLTC to select the specific reference cell RC is programmed in the fuse latch circuit 15-1. The arrangement of the fuse latch circuit 15-1 is the same as that shown in FIG. 10 of the first embodiment.

Switching of the two addresses AIN and FLTC is controlled by block activation signals BACT_1 and BACT_2. To access the memory cell MC included in the memory cell array 11-1 in FIG. 12, the block activation signal BACT_1 is activated. To access the memory cell MC included in the memory cell array 11-2, the block activation signal BACT_2 is activated. The arrangement of the multiplexer MUX is the same as that shown in FIG. 9 of the first embodiment.

The decoding unit 12A receives addresses bAD and AD from the multiplexer MUX. The decoding unit 12A activates one of the word lines WL1_1 to WL1_m based on the addresses bAD and AD.

Note that the row decoder 12-2 provided in correspondence with the memory cell array 11-2 has the same arrangement as that of the row decoder 12-1 described above.

With the operation of the row decoder 12, the specific reference cell RC is always selected in a block that does not include the memory cell MC to be accessed. In addition, when the address to be programmed in the fuse latch circuit 15 is changed, the reference cell RC to be used for read can be changed.

### [2-4] Effects

In the second embodiment, the plurality of reference cells RC connected to the reference bit lines RBL and arranged in the column direction are used as the reference cells RC necessary for the read operation of the memory cells MC. Cells that are arranged on the same column as that of the specific reference cell RC but not in use as the reference cells RC are set as the fuse cells FC. Hence, in this embodiment, the fuse cells FC are arranged on the same column as that of the reference cells RC in one cell array 10-1 or 10-2.

In this embodiment as well, it is therefore possible to implement the fuse cells FC without increasing the chip area, as in the above-described first embodiment. In addition, since the total number of reference cells RC can be decreased, the read margin can easily be ensured.

### [3] Third Embodiment

In the above-described embodiments, an MRAM is used as the resistance change memory. However, various memories other than the MRAM are also usable. In the third embodiment, an ReRAM (Resistance Random Access Memory) and a PRAM (Phase-change Random Access Memory) will be explained as other examples of the resistance change memory.

### [3-1] ReRAM

A resistance change element 21 used in an ReRAM will be described with reference to FIG. 14.

As shown in FIG. 14, the resistance change element 21 comprises a lower electrode 31, an upper electrode 35, and a recording layer 61 sandwiched between them.

The recording layer 61 is made of a transition metal oxide such as a perovskite metal oxide or a binary metal oxide. Examples of the perovskite metal oxide are PCMO (Pr_{0.7}Ca_{0.3}MnO₃), Nb-doped SrTi(Zr)O₃, and Cr-doped SrTi(Zr)O₃. Examples of the binary metal oxide are NiO, TiO₂, and Cu₂O.

The resistance change element 21 changes its resistance value by changing the polarity of the voltage applied thereto (bipolar type), or changes its resistance value by changing the absolute value of the voltage applied thereto (unipolar type). Hence, the resistance change element 21 is set in the low resistance state or the high resistance state by controlling the applied voltage. Note that whether the element is of the bipolar type or unipolar type depends on the material selected for the recording layer 61.

In the resistance change element 21 of the bipolar type, for example, the voltage that switches the resistance change element 21 from the high resistance state (reset state) to the low resistance state (set state) is a set voltage Vset, and the voltage that switches the resistance change element 21 from the low resistance state (set state) to the high resistance state (reset state) is a reset voltage Vreset. In this case, the set voltage Vset is set to a positive bias that applies a positive voltage to the upper electrode 35 with respect to the lower electrode 31, and the reset voltage Vreset is set to a negative bias that applies a negative voltage to the upper electrode 35 with respect to the lower electrode 31. Associating the low resistance state and the high resistance state with “0” data and “1” data, respectively, allows the resistance change element 21 to store 1-bit data.

To read data, a sufficiently small read voltage that is approximately 1/1000 to ¼ the reset voltage Vreset is applied to the resistance change element 21. Data can be read by detecting a current flowing through the resistance change element 21 at this time.

Note that the resistance change element 21 of the ReRAM shown in FIG. 14 is applicable in place of the MTJ element 21 of the memory cell MC or the fuse cell FC, or the fixed resistance element 23 of the reference cell RC in the MRAM of each of the above-described embodiments. In this case, the resistance change element 21 used in the reference cell RC is fixed to an intermediate resistance value (reference value) between the low resistance state and the high resistance state of the memory cell MC.

### [3-2] PRAM

The resistance change element 21 used in a PRAM will be described with reference to FIG. 15.

As shown in FIG. 15, the resistance change element 21 is formed by sequentially stacking the lower electrode 31, a heater layer 62, a recording layer 63, and the upper electrode 35.

The recording layer 63 is made of a phase-change material, and is set in a crystalline state or an amorphous state by heat generated in the write mode. Examples of the material of the recording layer 63 are chalcogen compounds such as Ge—Sb—Te, In—Sb—Te, Ag—In—Sb—Te, and Ge—Sn—Te. These materials are preferable for securing high-speed switching, repetition write stability, and high reliability.

The heater layer 62 is in contact with the bottom surface of the recording layer 63. The area of the heater layer 62 contacting the recording layer 63 is preferably smaller than the area of the bottom surface of recording layer 63. This is to make the heating part smaller by reducing the area of the contact portion between the heater layer 62 and the recording layer 63 and thus reduce the write current or voltage. The heater layer 62 is made of a conductive material, and preferably made of a material selected from, for example, TiN, TiAlN, TiBN, TiSiN, TaN, TaAlN, TaBN, TaSiN, WN, WAIN, WBN, WSiN, ZrN, ZrAlN, ZrBN, ZrSiN, MoN, Al, Al—Cu, Al—Cu—Si, WSi, Ti, Ti—W, and Cu. The heater layer 62 may be made of the same material as that of the lower electrode to be described later.

The area of the lower electrode 31 is larger than that of the heater layer 62. The upper electrode 35 has, for example, the same planar shape as that of the recording layer 63. Examples of the material of the lower electrode 31 and the upper electrode 35 are high-melting metals such as Ta, Mo and W.

The recording layer 63 switches to the crystalline state or the amorphous state as the heating temperature changes upon controlling the magnitude and width of a current pulse applied thereto. More specifically, in the write mode, a voltage or a current is applied between the lower electrode 31 and the upper electrode 35, and a current is supplied from the upper electrode 35 to the lower electrode 31 via the recording layer 63 and the heater layer 62. When heated to a temperature close to the melting point, the recording layer 63 changes to an amorphous phase (high resistance phase) and maintains the amorphous state even after the application of the voltage or the current has stopped.

On the other hand, when a voltage or a current is applied between the lower electrode 31 and the upper electrode 35, and the recording layer 63 is heated almost to a temperature suitable for crystallization, the recording layer 63 changes to a crystalline phase (low resistance phase), and maintains the crystalline state even after the application of the voltage or the current has stopped. To change the recording layer 63 to the crystalline state, the magnitude of the current pulse applied to the recording layer 63 is made smaller, and the width of the current pulse is made larger, as compared to the change to the amorphous state. Thus heating the recording layer 63 by applying a voltage or a current between the lower electrode 31 and the upper electrode 35 enables to change the resistance value of the recording layer 63.

Whether the recording layer 63 is in the crystalline phase or the amorphous phase can be determined by applying, between the lower electrode 31 and the upper electrode 35, such a low voltage or small current that causes neither crystallization nor noncrystallization in the recording layer 63 and reading the voltage or the current between the lower electrode 31 and the upper electrode 35. Hence, associating the low resistance state and the high resistance state with “0” data and “1” data, respectively, allows to read 1-bit data from the resistance change element 21.

Note that the resistance change element 21 of the PRAM shown in FIG. 15 is applicable in place of the MTJ element 21 of the memory cell MC or the fuse cell FC, or the fixed resistance element 23 of the reference cell RC in the MRAM of each of the above-described embodiments. In this case, the resistance change element 21 used in the reference cell RC is fixed to an intermediate resistance value (reference value) between the low resistance state and the high resistance state of the memory cell MC.

According to the above-described embodiments, it is possible to provide a semiconductor memory device capable of implementing fuse cells without increasing the chip area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first reference cell being arranged in a first cell array; and
a plurality of first fuse cells being arranged in the first cell array, the first reference cell and the plurality of first fuse cells being arranged on the same row or column.

2. The device according to claim 1, further comprising:
a memory cell being arranged in a second cell array different from the first cell array; and
a sense amplifier having inputs to which the memory cell and the first reference cell are connected when reading data of the memory cell.

3. The device according to claim 2, which further comprises a second fuse cell arranged in the second cell array and storing data complementary to data of the first fuse cell, and
in which when reading data of the first fuse cell and the second fuse cell, the first fuse cell and the second fuse cell are connected to the inputs of the sense amplifier.

4. The device according to claim 2, wherein when reading data of the memory cell, the first reference cell is accessed independently of an address of the memory cell.

5. The device according to claim 1, wherein
data of the first fuse cell is read out and transferred to a peripheral storage circuit immediately after the device is powered on, and
an operation condition of a peripheral control circuit is adjusted by the data transferred to the peripheral storage circuit.

6. A semiconductor memory device comprising:
a plurality of memory cells being arranged in a memory cell array;
a reference cell being arranged in the memory cell array and storing reference data in read operation of the memory cell; and
a fuse cell being arranged in the memory cell array and storing data with respect to a selection of the reference cell,
wherein the reference cell and the fuse cell are electrically connected to a common reference word line or a common reference bit line.

7. The device according to claim 6, wherein
the reference cell comprises a first resistance element and a first selection transistor,
the fuse cell comprise a second resistance element having a variable resistance value and a second selection transistor,
one end of the first resistance element is electrically connected to one end of the second resistance element through the reference bit line, and
a gate of the first selection transistor is electrically connected to a gate of the second selection transistor through the reference word line.

8. The device according to claim 6, which further comprises a sense amplifier shared between a first cell array and a second cell array,
in which the memory cell array has the first cell array and the second cell array,
when reading data stored in the memory cell of the second cell array, the sense amplifier determines the data of the memory cell of the second cell array based on a current or a voltage read out from the memory cell of the second cell array and a current or a voltage read out from the reference cell of the first cell array.

9. The device according to claim 7, which further comprises a sense amplifier shared between a first cell array and a second cell array,
in which the memory cell array has the first cell array and the second cell array,
when reading data stored in the memory cell of the second cell array, the sense amplifier determines the data of the memory cell of the second cell array based on a current or a voltage read out from the memory cell of the second cell array and a current or a voltage read out from the reference cell of the first cell array.

10. The device according to claim 8, wherein data stored in the fuse cell of the second cell array has a complement relation to data stored in the fuse cell of the first cell array.

11. The device according to claim 9, wherein data stored in the fuse cell of the second cell array has a complement relation to data stored in the fuse cell of the first cell array.

12. The device according to claim 8, further comprising:
a first row decoder being electrically connected to the first cell array through a first word line;
a first column decoder being electrically connected to the first cell array through a first bit line;
a second row decoder being electrically connected to the second cell array through a second word line;
a second column decoder being electrically connected to the second cell array through a second bit line; and
a peripheral storage circuit being electrically connected to the sense amplifier.

13. The device according to claim 10, further comprising:
a first row decoder being electrically connected to the first cell array through a first word line;
a first column decoder being electrically connected to the first cell array through a first bit line;
a second row decoder being electrically connected to the second cell array through a second word line;
a second column decoder being electrically connected to the second cell array through a second bit line; and
a peripheral storage circuit being electrically connected to the sense amplifier.

14. The device according to claim 12, wherein
the peripheral storage circuit has a first fuse latch circuit and a second fuse latch circuit,
the first fuse latch circuit is electrically connected to the first row decoder, and
the second fuse latch circuit is electrically connected to the second row decoder.

15. The device according to claim 13, wherein
the peripheral storage circuit has a first fuse latch circuit storing the data with respect to the selection of the reference cell and a second fuse latch circuit,
the first fuse latch circuit is electrically connected to the first row decoder, and
the second fuse latch circuit is electrically connected to the second row decoder.

16. The device according to claim 14, wherein the fuse cell stores data setting an operation condition of the peripheral storage circuit.

17. The device according to claim 15, wherein the fuse cell stores data setting an operation condition of the peripheral storage circuit.

18. The device according to claim 1, wherein the semiconductor memory device is an MRAM.

19. The device according to claim 6, wherein the semiconductor memory device is an MRAM.
